(19) United States
(12) Patent Application Publication
(10) Pub. No.: US 2025/0357412 A1
(43) Pub. Date: Nov. 20, 2025

(54) SEMICONDUCTOR DEVICE AND METHOD FOR MANUFACTURING THE SAME

(71) Applicant: Rohm Co., Ltd., Kyoto-shi (JP)

(72) Inventor: Tatsushi SUGAWARA, Kyoto-shi (JP)

(21) Appl. No.: 19/203,600

(22) Filed: May 9, 2025

(30) Foreign Application Priority Data
May 16, 2024 (JP) 2024-079996

(51) Int. Cl. H01L 23/00; H01L 23/31; H01L 23/495

(52) U.S. Cl. CPC H01L 24/45; H01L 23/3121; H01L 23/49562; H01L 24/48; H01L 24/49; H01L 24/78; H01L 23/49513; H01L 24/32; H01L 24/73; H01L 2224/32245; H01L 2224/45005; H01L 2224/45124; H01L 2224/45147; H01L 2224/48091; H01L 2224/48245; H01L 2224/48472; H01L 2224/4903; H01L 2224/73265; H01L 2224/7855; H01L 2924/10272; H01L 2924/13091

(57) ABSTRACT

A semiconductor device comprises a semiconductor element including a first electrode located on one side in a first direction, a first terminal electrically connected to the first electrode and a first wire conductively bonded to the first electrode and the first terminal. The first wire includes a main part, a first bond part connected to one end of the main part, and a second bond part connected to another end of the main part. The first bond part is conductively bonded to the first electrode. The second bond part is conductively bonded to the first terminal. As viewed in the first direction, a direction in which the second bond part extends differs from a direction in which the main part extends.

### FIELD

The present disclosure relates to a semiconductor device and a method for manufacturing the same.

### BACKGROUND

JP-A-2018-14490 discloses an example of a semiconductor device, which includes a first semiconductor element, and a first lead and a third lead each electrically connected to the first semiconductor element. The first semiconductor element is a switching element, such as a MOSFET. In the semiconductor device, when the first semiconductor device is turned on, a current flows from the first lead to the third lead. The semiconductor device is used, for example, as an element constituting a circuit of a DC-DC converter.

The semiconductor device disclosed in J P-A-2018-14490 further includes a second wire conductively bonded to the first semiconductor element and the third lead. To allow a larger current to flow in the third lead, the cross sectional area of the second wire may be made larger. In such a case, the heat conducted from the first semiconductor element to the second wire generates thermal stress in the second wire. When the thermal stress generated in the second wire increases, the shear stress acting on the interface between the third lead and the second wire increases, which may result in separation of the second wire from the third lead.

### DRAWINGS

FIG. 1 is a plan view of a semiconductor device according to a first embodiment of the present disclosure.

FIG. 2 is a plan view corresponding to FIG. 1, in which a sealing resin is transparent.

FIG. 3 is a bottom view of the semiconductor device shown in FIG. 1.

FIG. 4 is a front view of the semiconductor device shown in FIG. 1.

FIG. 5 is a right side view of the semiconductor device shown in FIG. 1.

FIG. 6 is a sectional view taken along line VI-VI in FIG. 2.

FIG. 7 is a sectional view taken along line VII-VII in FIG. 2.

FIG. 8 is a sectional view taken along line VIII-VIII in FIG. 2.

FIG. 9 is a partial enlarged view of FIG. 3.

FIG. 10 is a partial enlarged view of FIG. 7.

FIG. 11 is a partial enlarged sectional view illustrating a manufacturing method of the semiconductor device shown in FIG. 1.

FIG. 12 is a partial enlarged sectional view illustrating the manufacturing method of the semiconductor device shown in FIG. 1.

FIG. 13 is a partial enlarged sectional view illustrating the manufacturing method of the semiconductor device shown in FIG. 1.

FIG. 14 is a a partial enlarged sectional view illustrating the manufacturing method of the semiconductor device shown in FIG. 1.

FIG. 15 is a partial enlarged plan view corresponding to FIG. 9, showing a semiconductor device according to a first variation of the first embodiment of the present disclosure.

FIG. 16 is a partial enlarged plan view corresponding to FIG. 9, showing a semiconductor device according to a second variation of the first embodiment of the present disclosure.

FIG. 17 is a partial enlarged plan view corresponding to FIG. 9, showing a semiconductor device according to a third variation of the first embodiment of the present disclosure.

FIG. 18 is a sectional view corresponds to FIG. 7, showing a semiconductor device according to a second embodiment of the present disclosure.

FIG. 19 is a sectional view corresponding to FIG. 8, showing the semiconductor device of FIG. 18.

FIG. 20 is a plan view of a semiconductor device according to a third embodiment of the present disclosure, in which the sealing resin is transparent.

### EMBODIMENTS

The following describes preferred embodiments of the present disclosure in detail with reference to the accompanying drawings.

### First Embodiment

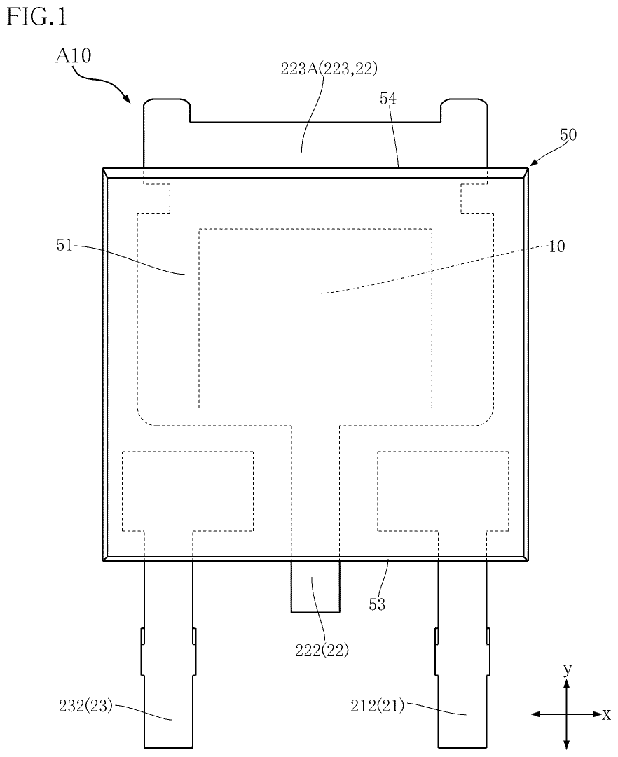

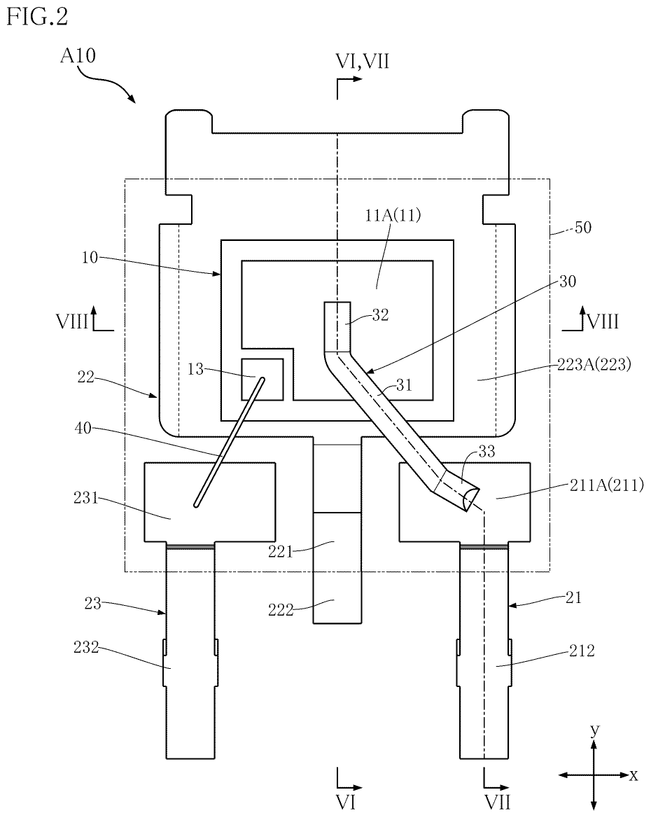

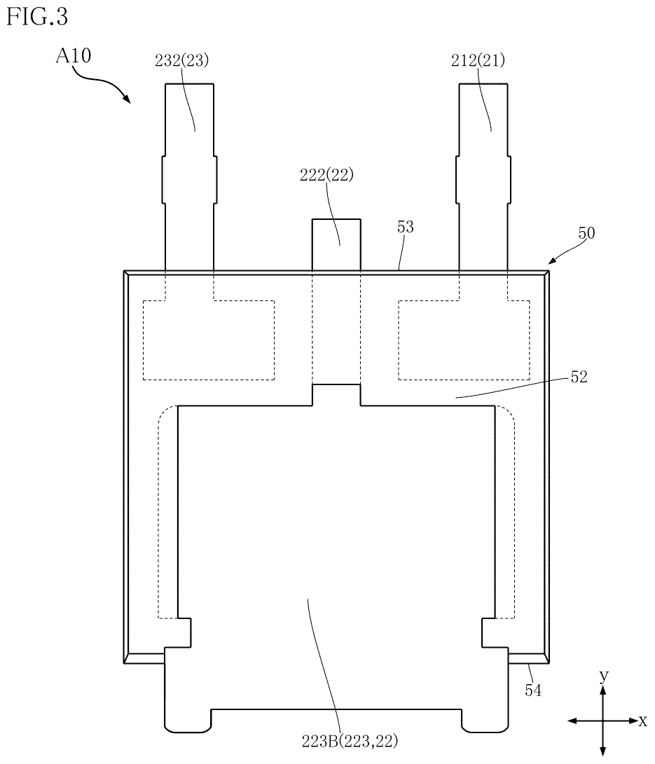

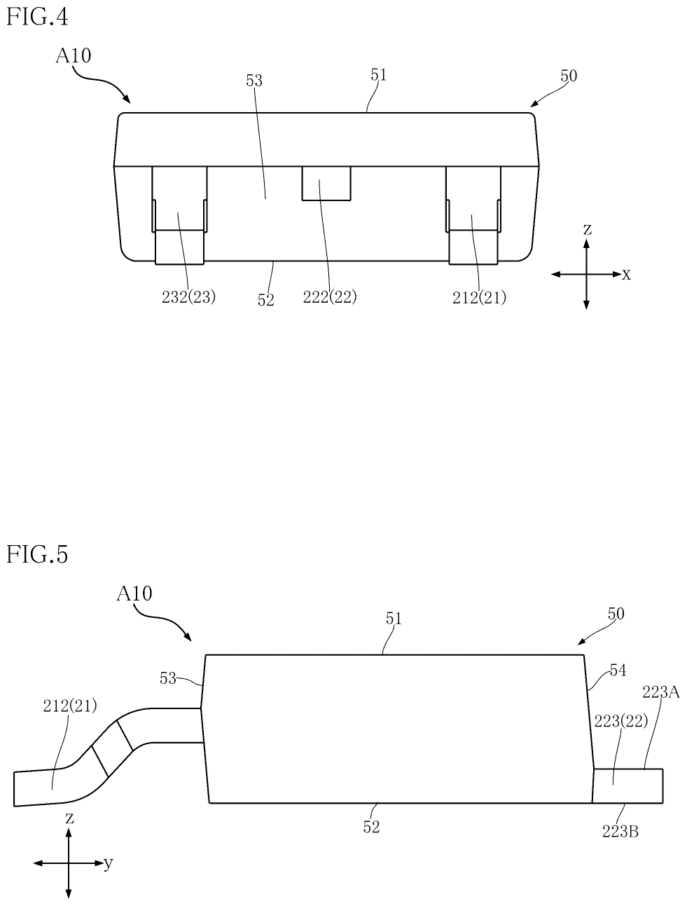

A semiconductor device A10 according to a first embodiment of the present disclosure will be described based on FIGS. 1 to 10. The semiconductor device A10 is of a surface-mount package type. The semiconductor device A10 includes a semiconductor element 10, a first terminal 21, a second terminal 22, a third terminal 23, a bonding layer 29, a first wire 30, a second wire 40, and a sealing resin 50. In FIG. 2, the sealing resin 50 is transparent for convenience of understanding. In FIG. 2, the outline of the sealing resin 50 is indicated by imaginary lines (two-dot chain lines).

In the description of the semiconductor device A10, for convenience, the direction normal to the first surface 211A of the first terminal 21, which will be described later, is referred to as the “first direction z”. A direction orthogonal to the first direction z is referred to as the “second direction x”. The direction orthogonal to the first direction z and the second direction x is referred to as the “third direction y”.

The semiconductor element 10 is, for example, a MOSFET (Metal-Oxide-Semiconductor Field-Effect Transistor (MOSFET). Alternatively, the semiconductor element 10 may be a field-effect transistor including a MISFET (Metal-Insulator-Semiconductor Field-Effect Transistor) or a bipolar transistor such as an IGBT (Insulated Gate Bipolar Transistor). In the semiconductor device A10 described herein, the semiconductor element 10 is an n-channel MOSFET having a vertical structure. The semiconductor element 10 includes a compound semiconductor substrate. The composition of the compound semiconductor substrate includes silicon carbide (SIC).

As shown in FIGS. 2 and 10, the semiconductor element 10 has a first electrode 11, a second electrode 12, and a third electrode 13. The first electrode 11 is located on one side in the first direction z. The second electrode 12 is located opposite to the first electrode 11 in the first direction z. The third electrode 13 is located on the same side as the first electrode 11 in the first direction z. A voltage is applied to each of the first electrode 11 and the second electrode 12. A gate voltage for driving the semiconductor element 10 is applied to the third electrode 13. When the semiconductor element 10 is turned on by the gate voltage being applied to the third electrode 13, a current flows from the second electrode 12 to the first electrode 11. The first electrode 11 has a second surface 11A facing the above one side in the first direction z.

The first terminal 21, the second terminal 22, and the third terminal 23 are used when the semiconductor device A10 is mounted on a circuit board. The first terminal 21, the second terminal 22, and the third terminal 23 are obtained from the same lead frame. The lead frame is made of copper (Cu) or a copper alloy. Thus, the composition of the first terminal 21, the second terminal 22, and the third terminal 23 includes copper.

As shown in FIGS. 2 and 6, the second terminal 22 has a second inner portion 221, a second outer portion 222, and a pad portion 223. The pad portion 223 has the semiconductor element 10 mounted thereon. The pad portion 223 has a mount surface 223A and a reverse surface 223B. The mount surface 223A faces the same side as the second surface 11A of the first electrode 11 of the semiconductor element 10 in the first direction z. At least a portion of the mount surface 223A is covered with the sealing resin 50. The reverse surface 223B faces away from the mount surface 223A in the first direction z. The reverse surface 223B is, for example, plated with tin (Sn). The reverse surface 223B is exposed from the sealing resin 50.

As shown in FIG. 6, the second outer portion 222 protrudes from the sealing resin 50 to the side opposite to the side where the pad portion 223 is located in the third direction y. The surface of the second outer portion 222 is, for example, plated with tin. The second inner portion 221 connects the pad portion 223 and the second outer portion 222 to each other. As viewed in the second direction x, the second inner portion 221 is bent. The second inner portion 221 is covered with the sealing resin 50.

As shown in FIG. 10, the bonding layer 29 conductively bonds the mount surface 223A of the pad portion 223 and the second electrode 12 of the semiconductor element 10 to each other. Thus, the second terminal 22 is electrically connected to the second electrode 12. The bonding layer 29 is, for example, solder. Alternatively, the bonding layer 29 may be sintered metal particles. The metal particles include, for example, silver (Ag).

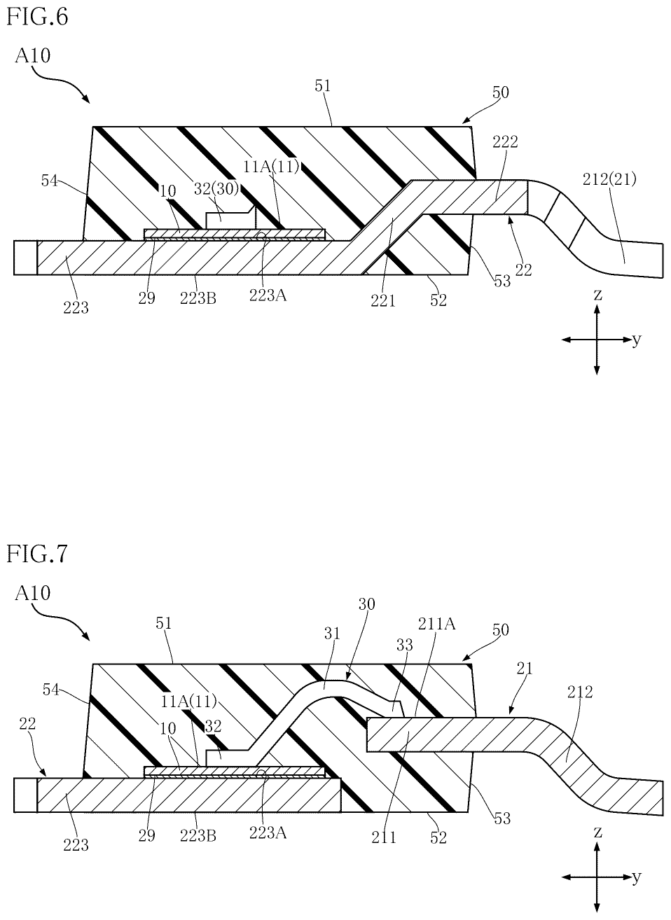

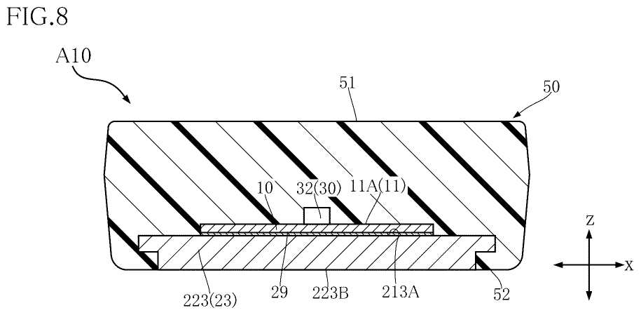

As shown in FIG. 2, the first terminal 21 is spaced apart from the second inner portion 221 and the second outer portion 222 of the second terminal 22 to one side in the second direction x. The first terminal 21 is located on the same side as the second inner portion 221 and the second outer portion 222 with respect to the pad portion 223 of the second terminal 22 in the third direction y. The first terminal 21 is electrically connected to the first electrode 11 of the semiconductor element 10. As shown in FIGS. 2 and 7, the first terminal 21 has a first inner portion 211 and a first outer portion 212. The first inner portion 211 is covered with the sealing resin 50. The first inner portion 211 has a first surface 211A facing the same side as the second surface 11A of the semiconductor element 10 (the first electrode 11) in the first direction z. The first outer portion 212 is connected to the first inner portion 211. The first outer portion 212 protrudes from the sealing resin 50 to the side opposite to the side where the first inner portion 211 is located in the third direction y. As shown in FIG. 5, the first outer portion 212 is bent into a gull wing shape as viewed in the second direction x. The surface of the first outer portion 212 is, for example, plated with tin.

As shown in FIG. 2, the third terminal 23 is located opposite to the first terminal 21 with respect to the second inner portion 221 and the second outer portion 222 of the second terminal 22 in the second direction x. The third terminal 23 is electrically connected to the third electrode 13 of the semiconductor element 10. As shown in FIG. 2, the third terminal 23 has a third inner portion 231 and a third outer portion 232. The third inner portion 231 is covered with the sealing resin 50. The third outer portion 232 is connected to the third inner portion 231. The third outer portion 232 protrudes from the sealing resin 50 to the side opposite to the side where the third inner portion 231 is located in the third direction y. The third outer portion 232 is bent into a gull wing shape as viewed in the second direction x. The surface of the third outer portion 232 is, for example, plated with tin.

As shown in FIGS. 2 and 7, the first wire 30 is conductively bonded to the first electrode 11 of the semiconductor element 10 and the first inner portion 211 of the first terminal 21. Thus, the first terminal 21 is electrically connected to the first electrode 11. The first wire 30 contains aluminum (Al). Alternatively, the first wire 30 may contain copper.

As shown in FIGS. 2 and 7, the first wire 30 has a main part 31, a first bond part 32, and a second bond part 33. The first bond part 32 is connected to one end of the main part 31. The first bond part 32 is conductively bonded to the second surface 11A of the semiconductor element (the first electrode 11). The second bond part 33 is connected to the other end of the main part 31. The second bond part 33 is conductively bonded to the first surface 211A of the first terminal 21 (the first inner portion 211).

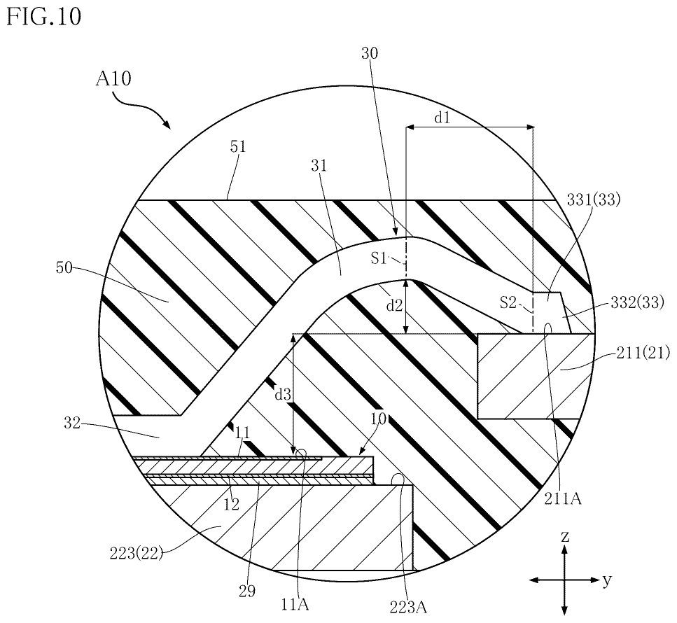

As shown in FIG. 9, the direction in which each of the first bond part 32 and the second bond part 33 extends differs from the direction in which the main part 31 extends. As viewed in the first direction z, the direction in which the second bond part 33 extends differs from the direction in which the first bond part 32 extends. In the semiconductor device A10, the first bond part 32 extends along the third direction y. The second bond part 33 extends from the main part 31 to be away from the second inner portion 221 of the second terminal 22 in the second direction x. In the semiconductor device A10, the angle α2 formed between the main part 31 and the second bond part 33 is greater than the angle α1 formed between the main part 31 and the first bond part 32, as viewed in the first direction z.

As shown in FIG. 10, the main part 31 includes a first cross section S1 and a second cross section S2, which are sections perpendicular to the direction in which it extends. The first cross section S1 is located farthest from the first surface 211A of the first terminal 21 in the first direction z. The second cross section S2 forms the boundary between the main part 31 and the second bond part 33. The ratio of the second distance d2 to the first distance d1 is 25% or more. Here, the first distance d1 is the minimum distance between the first cross section S1 and the second cross section S2 as viewed in the first direction z. The second distance d2 is the distance between the first surface 211A and the first cross section S1 in the first direction z. Also, the sum of the second distance d2 and the dimension in the first direction z of the first cross section S1 is 150% or more of the dimension in the first direction z of the first cross section S1. As shown in FIG. 10, the dimension in the first direction z of the first cross section S1 of the main part 31 is greater than the dimension in the first direction z of the semiconductor element 10.

As shown in FIG. 10, the first surface 211A of the first terminal 21 is located between the second surface 11A of the semiconductor element 10 and the first cross section S1 of the main part 31 in the first direction z. In the semiconductor device A10, the sum of the second distance d2 and the dimension in the first direction z of the first cross section S1 is smaller than the third distance d3. Here, the third distance d3 is the distance between the first surface 211A and the second surface 11A in the first direction z. In this case, the sum of the second distance d2 and the dimension in the first direction z of the first cross section S1 is 70% or more of the third distance d3. Alternatively, the sum of the second distance d2 and the dimension in the first direction z of the first cross section S1may be greater than the third distance d3. In such a case, the sum of the second distance d2 and the dimension in the first direction z of the first cross section S1 exceeds 100% of the third distance d3.

As shown in FIGS. 9 and 10, the second bond part 33 includes a first portion 331, and a second portion 332 connected to the first portion 331. The first portion 331 is connected to the second cross section S2 of the main part 31. The second portion 332 is located opposite to the main part 31 with respect to the first portion 331. The dimension in the first direction z of the second portion 332 is smaller than the dimension in the first direction z of the second cross section S2. The dimension in the first direction z of the second portion 332 gradually decreases with increasing distance from the first portion 331. As viewed in the first direction z, the dimension of the second portion 332 in the direction in which it extends is smaller than the dimension of the first portion 331 in the direction in which it extends.

As shown in FIG. 2, the second wire 40 is conductively bonded to the third electrode 13 of the semiconductor element 10 and the third inner portion 231 of the third terminal 23. Thus, the third terminal 23 is electrically connected to the third electrode 13. The second wire 40 contains, for example, aluminum or gold (Au). The diameter of the second wire 40 is smaller than the dimension in the first direction z of the first cross section S1 of the first wire 30 (the main part 31).

As shown in FIGS. 6 to 8, the sealing resin 50 covers the semiconductor element 10, the first wire 30, and the second wire 40. The sealing resin 50 has electrical insulation properties. The sealing resin 50 is made of a material containing, for example, a black epoxy resin. The sealing resin 50 has a third surface 51, a fourth surface 52, a first side surface 53, a second side surface 54, and two third side surfaces 45.

As shown in FIGS. 6 to 8, the third surface51 faces the same side as the first surface 211A of the first terminal 21 (the first inner portion 211) in the first direction z. The fourth surface52 faces away from the third surface 51 in the first direction z. The reverse surface 223B of the pad portion 223 of the second terminal 22 is exposed from the fourth surface 52.

As shown in FIGS. 1, 3, 6, and 7, the first side surface 53 and the second side surface 54 face away from each other in the third direction y. Each of the first side surface 53 and the second side surface 54 is connected to the third surface51 and the fourth surface 52. The first outer portion 212 of the first terminal 21, the second outer portion 222 of the second terminal 22, and the third outer portion 232 of the third terminal 23 protrude from the first side surface 53 in the third direction y. A portion of the pad portion 223 of the second terminal 22 protrudes from the second side surface 54 in the third direction y.

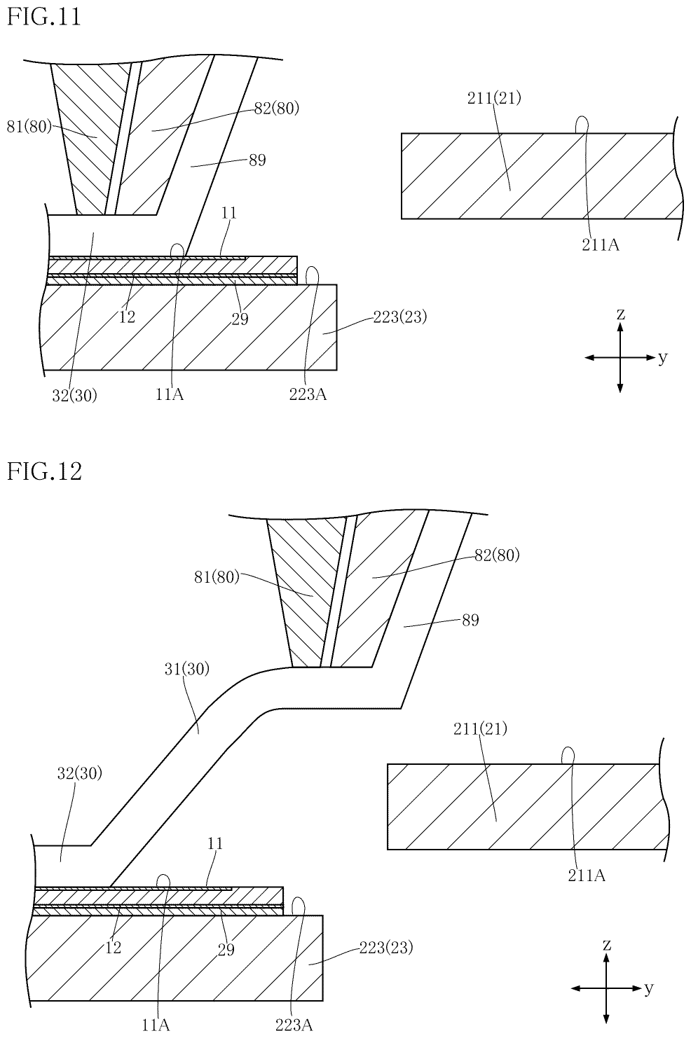

Next, a process of forming the first wire 30 in the manufacturing method of the semiconductor device A10 will be described based on FIGS. 11 to 14. In forming the first wire 30, a bonding tool 80 is used. The bonding tool 80 includes a wedge portion 81, a guide portion 82, and a cutting portion 83. In the step of forming the first wire 30, the first bond part 32, the main part 31, and the second bond part 33 are formed in this order by working a metal material 89 using the bonding tool 80. The metal material 89 includes aluminum. Here, the cross sectional position in FIGS. 11 to 14 corresponds to the cross sectional position in FIG. 7.

First, as shown in FIG. 11, the first bond part 32 conductively bonded to the second surface 11A of the semiconductor element 10 (the first electrode 11) is formed. The first bond part 32 is formed by pressing the wedge portion 81 against the metal material 89 fed from the guide portion 82.

Next, the main part 31 is formed as shown in FIG. 12. The main part 31 is formed by moving the bonding tool 80 away from the semiconductor element 10 in the first direction z.

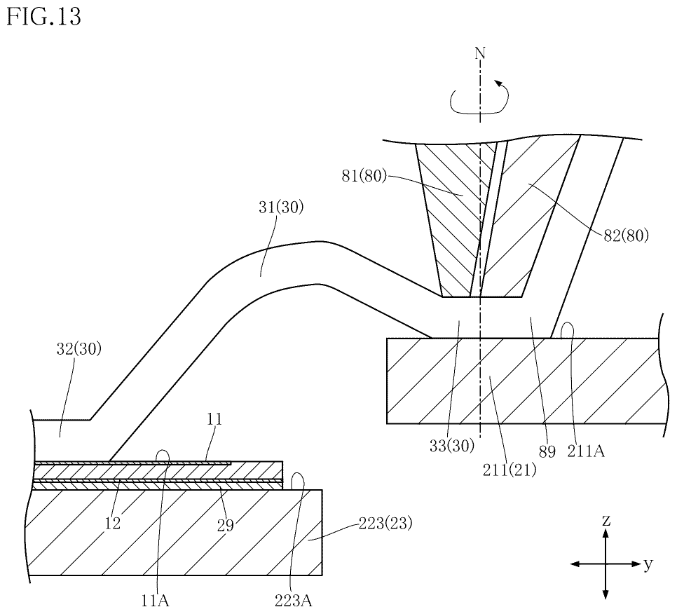

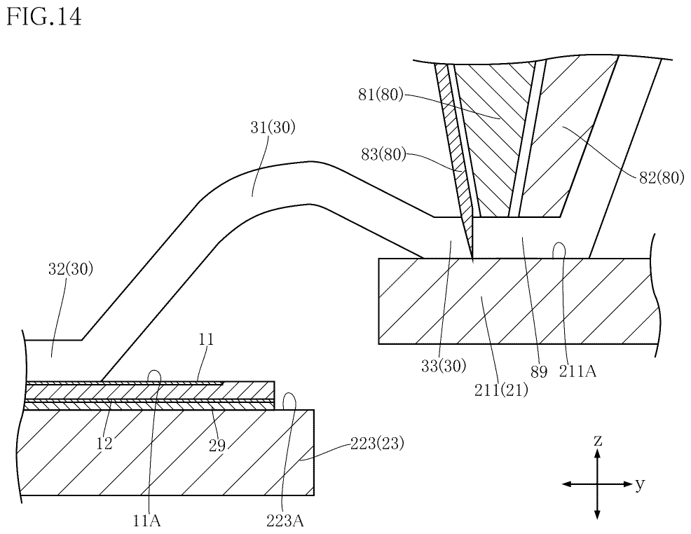

Next, as shown in FIGS. 13 and 14, the second bond part 33 conductively bonded to the first surface 211A of the first terminal 21 (the first inner portion 211) is formed. First, as shown in FIG. 13, after the bonding tool 80 is turned around the axis N, the wedge portion 81 is pressed against the metal material 89 fed from the guide portion 82. The axis N extends along the first direction z. Next, as shown in FIG. 14, the second bond part 33 is cut away from the metal material 89 by the cutting portion 83. The formation of the first wire 30 is thus completed.

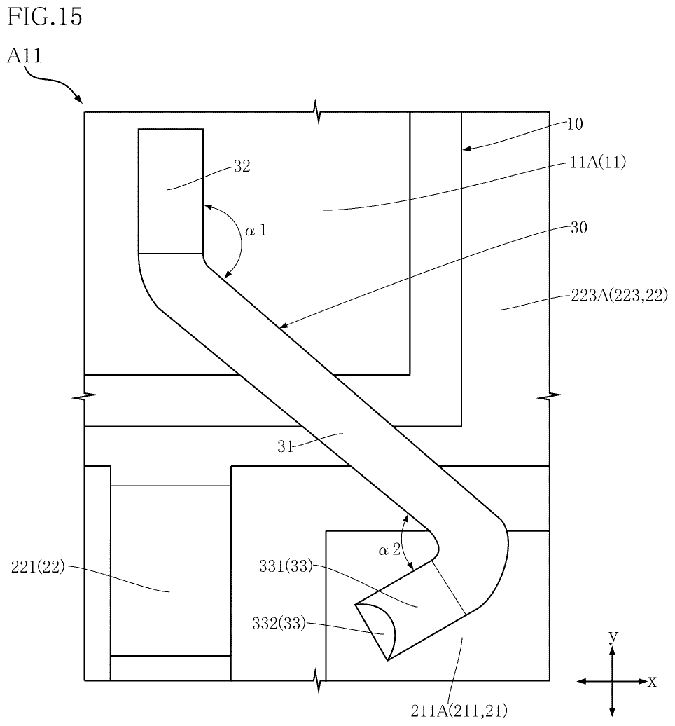

Next, a semiconductor device A11 according to a first variation of the first embodiment of the present disclosure will be described based on FIG. 15. FIG. 15 corresponds to FIG. 9, which shows the semiconductor device A10. The semiconductor device A11 differs from the semiconductor device A10 in the configuration of the first wire 30.

As shown in FIG. 15, in the semiconductor device A11, the first bond part 32 extends along the third direction y. The second bond part 33 extends from the main part 31 toward the second inner portion 221 of the second terminal 22 in the second direction x. Also, in the semiconductor device A11, the angle α2 formed between the main part 31 and the second bond part 33 is smaller than the angle α1 formed between the main part 31 and the first bond part 32, as viewed in the first direction z.

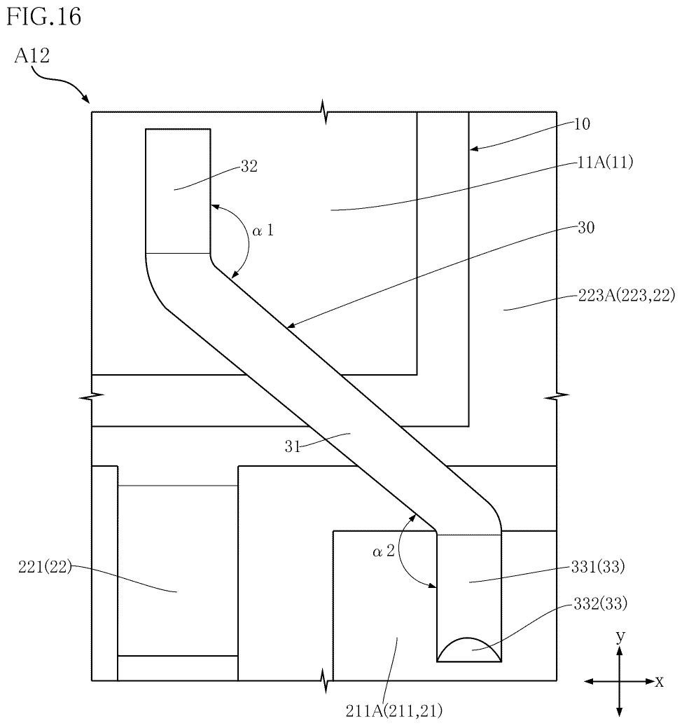

Next, a semiconductor device A12 according to a second variation of the first embodiment of the present disclosure will be described based on FIG. 16. FIG. 16 corresponds to FIG. 9, which shows the semiconductor device A10. The semiconductor device A12 differs from the semiconductor device A10 in the configuration of the first wire 30.

As shown in FIG. 16, in the semiconductor device A12, each of the first bond part 32 and the second bond part 33 extends along the third direction y. Thus, in the semiconductor device A12, the direction in which the second bond part 33 extends is the same as the direction in which the first bond part 32 extends. Also, in the semiconductor device A12, the angle α2 formed between the main part 31 and the second bond part 33 is equal to the angle α1 formed between the main part 31 and the first bond part 32, as viewed in the first direction z.

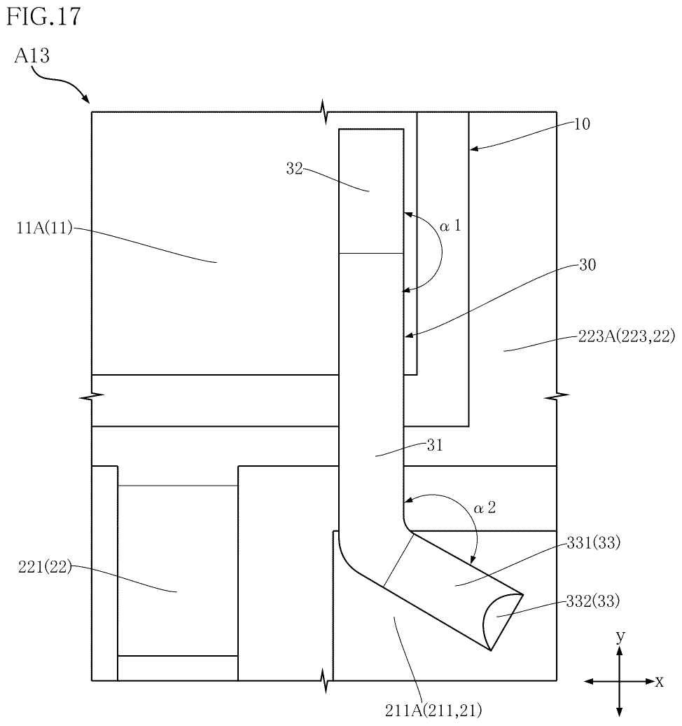

Next, a semiconductor device A13 according to a third variation of the first embodiment of the present disclosure will be described based on FIG. 17. FIG. 17 corresponds to FIG. 9, which shows the semiconductor device A10. The semiconductor device A13 differs from the semiconductor device A10 in the configuration of the first wire 30.

As shown in FIG. 17, in the semiconductor device A13, each of the main part 31 and the first bond part 32 extends along the third direction y. Thus, in the semiconductor device A13, the direction in which the first bond part 32 extends is the same as the direction in which the main part 31 extends. Also, in the semiconductor device A13, the angle α2 formed between the main part 31 and the second bond part 33 is smaller than the angle α1 (=) 180° formed between the main part 31 and the first bond part 32, as viewed in the first direction z.

As understood from the above, in the configuration of the first wire 30 of the semiconductor devices A10 to A13, it is essential that the direction in which the second bond part 33 extends differs from the direction in which the main part 31 extends as viewed in the first direction z. In the configuration of the first wire 30 of the semiconductor devices A10 to A13, it is possible to freely set the directions in which the first bond part 32 and the second bond part 33 extend with respect to the main part 31 as viewed in the first direction z, and the magnitude relationship between the angle α1 and the angle α2.

Next, the effects of the semiconductor device A10 will be described.

The semiconductor device A10 includes the semiconductor element 10, the first terminal 21, and the first wire 30. The first wire 30 has the main part 31, the first bond part 32, and the second bond part 33. The first bond part 32 is conductively bonded to the first electrode 11 of the semiconductor element 10. The second bond part 33 is conductively bonded to the first terminal 21. As viewed in the first direction z, the direction in which the second bond part 33 extends differs from the direction in which the main part 31 extends. By adopting this configuration, the thermal stress transferred from the main part 31 to the second bond part 33 in the first wire 30 is divided into a component flowing in the direction in which the main part 31 extends as viewed in the first direction z and a component flowing in a direction orthogonal to the direction in which the main part 31 extends as viewed in the first direction z. As a result, at the interface between the first terminal 21 and the second bond part 33, the shear stress flowing in the direction in which the main part 31 extends as viewed in the first direction z is reduced. Thus, according to the present configuration, the semiconductor device A10 can suppress separation of the first wire 30 from the first terminal 21.

As viewed in the first direction z, the direction in which the first bond part 32 extends differs from the direction in which the main part 31 extends. By adopting this configuration, of the thermal stress transferred from the first bond part 32 to the main part 31 in the first wire 30, the component flowing in the direction in which the main part 31 extends as viewed in the first direction z can be reduced.

The main part 31 includes the first cross section S1 and the second cross section S2, which are sections perpendicular to the direction in which it extends. The first terminal 21 has the first surface 211A to which the second bond part 33 is conductively bonded. The ratio of the second distance d2 between the first surface 211A and the first cross section S1 in the first direction z to the first distance d1 between the first cross section S1 and the second cross section S2 in the first direction z is 25% or more. By adopting this configuration, the inclination angle of the main part 31 with respect to the second bond part 33 can be set to be larger. This allows the thermal stress transferred from the main part 31 to the second bond part 33 in the first wire 30 to be reduced.

The first electrode 11 of the semiconductor element 10 has the second surface 11A to which the first bond part 32 is conductively bonded. The first surface 211A of the first terminal 21 is located between the second surface 11A and the first cross section S1 of the main part 31 in the first direction z. With such a configuration, by setting a larger inclination angle of the main part 31 with respect to the second bond part 33, separation of the first wire 30 from the first terminal 21 can be effectively suppressed.

The dimension of the first cross section S1 of the main part 31 is greater than the dimension in the first direction z of the semiconductor element 10. Adopting this configuration allows a larger current to flow in the first wire 30.

The first wire 30 contains copper. The ionization tendency of copper is lower than that of aluminum. Also, the linear expansion coefficient of copper is lower than that of aluminum. By adopting this configuration, separation of the first wire 30 from the first terminal 21 can be effectively suppressed, and breakage of the first wire 30 can be effectively prevented when pitting corrosion caused by thermal stress occurs in the first wire 30.

The semiconductor device A10 further includes the second terminal 22 having the pad portion 223. The pad portion 223 has the reverse surface 223B. The reverse surface 223B is exposed from the sealing resin 50. By adopting this configuration, heat generated from the semiconductor element 10 can be efficiently dissipated to the outside.

### Second Embodiment

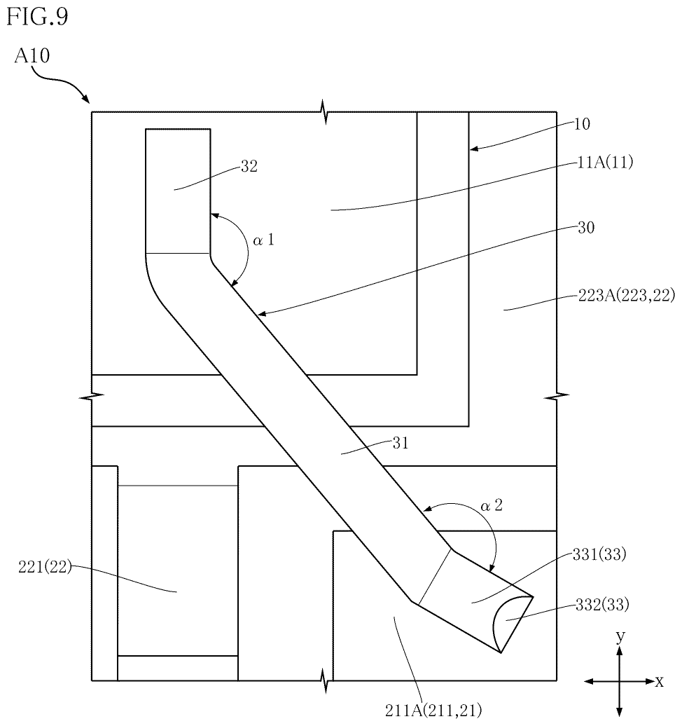

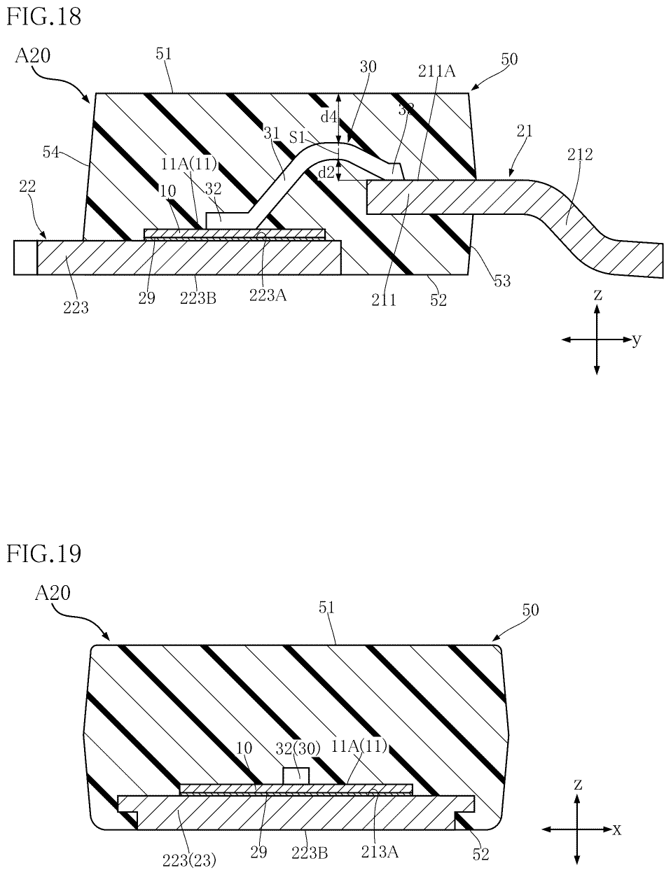

A semiconductor device A20 according to a second embodiment of the present disclosure will be described based on FIGS. 18 and 19. In these figures, the elements that are identical or similar to those of the semiconductor device A10 described above are denoted by the same reference signs, and the descriptions thereof are omitted. FIGS. 18 and 19 correspond to FIGS. 7 and 8, respectively, which show the semiconductor device A10.

The semiconductor device A20 differs from the semiconductor device A10 in the configuration of the sealing resin 50.

As shown in FIGS. 18 and 19, the dimension in the first direction z of the sealing resin 50 (the distance from the third surface 51 to the fourth surface 52 in the first direction z) is greater than that in the semiconductor device A10. As shown in FIG. 18, the fourth distance d4 is greater than the sum of the second distance d2 and the dimension in the first direction z of the first cross section S1 of the first wire 30. Here, the fourth distance d4 is the distance between the third surface 51 of the sealing resin 50 and the first cross section S1 in the first direction z.

Next, the effects of the semiconductor device A20 will be described.

The semiconductor device A20 includes the semiconductor element 10, the first terminal 21, and the first wire 30. The first wire 30 has the main part 31, the first bond part 32, and the second bond part 33. The first bond part 32 is conductively bonded to the first electrode 11 of the semiconductor element 10. The second bond part 33 is conductively bonded to the first terminal 21. As viewed in the first direction z, the direction in which the second bond part 33 extends differs from the direction in which the main part 31 extends. Thus, according to the present configuration, the semiconductor device A20 can also suppress separation of the first wire from the first terminal 21. Also, the semiconductor device A20 has a configuration in common with the semiconductor device A10, thereby achieving the same effect as the semiconductor device A10.

In the semiconductor device A20, the fourth distance d4 between the third surface 51 of the sealing resin 50 and the first cross section S1 of the first wire 30 in the first direction z is greater than the sum of the second distance d2 and the dimension in the first direction z of the first cross section S1. By adopting this configuration, the minimum dimension in the first direction z of the portion of the sealing resin 50 that includes the third surface 51 and covers the first wire 30 can be increased. This allows the dielectric strength of the semiconductor device A20 to be improved while providing reliable protection of the first wire 30 from external factors.

### Third Embodiment

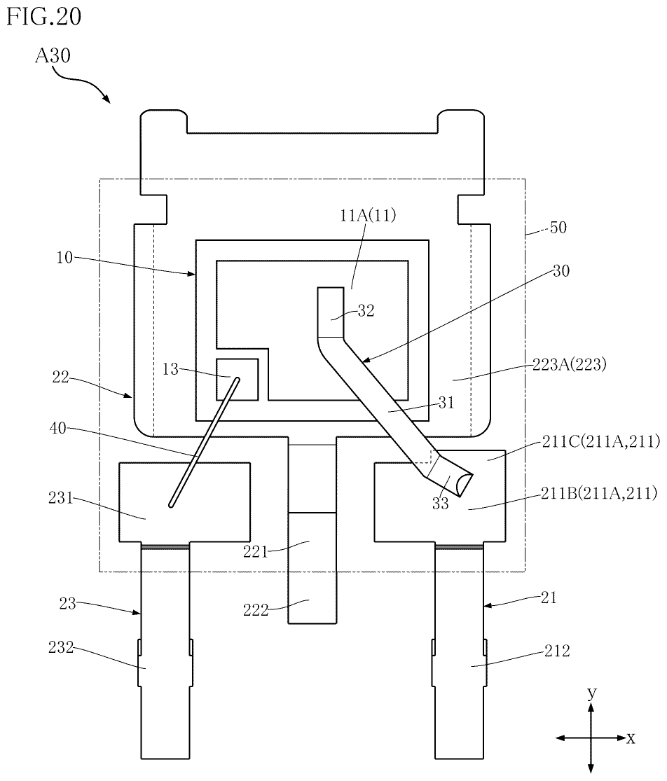

A semiconductor device A30 according to a third embodiment of the present disclosure will be described based on FIG. 20. In these figures, the elements that are identical or similar to those of the semiconductor device A10 described above are denoted by the same reference signs, and the descriptions thereof are omitted. In FIG. 20, the sealing resin 50 is transparent. In FIG. 20, the outline of the sealing resin 50 is indicated by imaginary lines.

The semiconductor device A30 differs from the semiconductor device A10 in the configuration of the first terminal 21.

As shown in FIG. 20, the first surface 211A of the first inner portion 211 of the first terminal 21 includes a first region 211B and a second region 211C. As viewed in the first direction z, the second region 211C extends from the first region 211B to the side where the semiconductor element 10 is located. As viewed in the first direction z, the main part 31 of the first wire 30 overlaps with each of the first region 211B and the second region 211C.

Next, the effects of the semiconductor device A30 will be described.

The semiconductor device A30 includes the semiconductor element 10, the first terminal 21, and the first wire 30. The first wire 30 has the main part 31, the first bond part 32, and the second bond part 33. The first bond part 32 is conductively bonded to the first electrode 11 of the semiconductor element 10. The second bond part 33 is conductively bonded to the first terminal 21. As viewed in the first direction z, the direction in which the second bond part 33 extends differs from the direction in which the main part 31 extends. Thus, according to the present configuration, the semiconductor device A30 can also suppress separation of the first wire from the first terminal 21. Also, the semiconductor device A30 has a configuration in common with the semiconductor device A10, thereby achieving the same effect as the semiconductor device A10.

In the semiconductor device A30, the first surface 211A of the first terminal 21 includes the first region 211B and the second region 211C. As viewed in the first direction z, the main part 31 of the first wire 30 overlaps with each of the first region 211B and the second region 211C. By adopting this configuration, when forming the first wire 30 in the manufacture of the semiconductor device A10, even if the position of the second bond part 33 relative to the first surface 211A deviates from the design, the second bond part 33 can be conductively bonded to the first surface 211A reliably.

The present disclosure is not limited to the above-described embodiments. Various modifications in design may be made freely in the specific structure of each part of the present disclosure. In the present disclosure, the semiconductor element 10 may be various elements, such as an LSI or a diode, rather than a switching element as in the semiconductor devices A10 to A30. That is, the type of the semiconductor element 10 is not limited to that in the above-described embodiments.

The present disclosure includes the embodiments described in the following clauses.

### Clause 1.

A semiconductor device (A10) comprising:
a semiconductor element (10) including a first electrode (11) located on one side in a first direction (z);
a first terminal (21) electrically connected to the first electrode (11); and
a first wire (30) conductively bonded to the first electrode (11) and the first terminal (21), wherein
the first wire (30) includes a main part (31), a first bond part (32) connected to one end of the main part (31), and a second bond part (33) connected to another end of the main part (31),
the first bond part (32) is conductively bonded to the first electrode (11),
the second bond part (33) is conductively bonded to the first terminal (21), and
as viewed in the first direction (z), a direction in which the second bond part (33) extends differs from a direction in which the main part (31) extends.

### Clause 2.

The semiconductor device (A10) according to clause 1, wherein as viewed in the first direction (z), a direction in which the first bond part (32) extends differs from the direction in which the main part (31) extends.

### Clause 3.

The semiconductor device (A10) according to clause 2, wherein as viewed in the first direction (z), the direction in which the second bond part (33) extends differs from the direction in which the first bond part (32) extends.

### Clause 4.

The semiconductor device (A10) according to clause 2, wherein the first terminal (21) includes a first surface (211A) which faces the one side in the first direction and to which the second bond part (33) is conductively bonded,
the main part (31) includes a first cross section (S1) and a second cross section (S2) that are sections perpendicular to the direction in which the main part (31) extends,
the first cross section (S1) is located farthest from the first surface (211A) in the first direction (z),
the second cross section (S2) forms a boundary between the main part (31) and the second bond part (33), and
a ratio of a second distance (d2) between the first surface (211A) and the first cross section (S1) in the first direction (z) to a first distance (d1) between the first cross section (S1) and the second cross section (S2) as viewed in the first direction (z) is 25% or more.

### Clause 5.

The semiconductor device (A10) according to clause 4, wherein a dimension in the first direction (z) of the first cross section (S1) is greater than a dimension in the first direction (z) of the semiconductor element (10).

### Clause 6.

The semiconductor device (A10) according to clause 4, wherein the first electrode (11) includes a second surface (11A) which faces the same side as the first surface (211A) in the first direction (z) and to which the first bond part (32) is conductively bonded, and
the first surface (211A) is located between the second surface (11A) and the first cross section (S1) in the first direction (z).

### Clause 7.

The semiconductor device (A10) according to clause 6, wherein a sum of the second distance (d2) and a dimension in the first direction (z) of the first cross section (S1) is smaller than a third distance (d3) between the first surface (211A) and the second surface (11A) in the first direction (z).

### Clause 8.

The semiconductor device (A10) according to clause 7, wherein the second bond part (33) includes a first portion (331) connected the main part (31) and a second portion (332) located opposite to the main part (31) with respect to the first portion (331), and
a dimension in the first direction (z) of the second portion (332) is smaller than a dimension in the first direction (z) of the second cross section (S2).

### Clause 9.

The semiconductor device (A10) according to clause 8, wherein as viewed in the first direction (z), a dimension of the second portion (332) in a direction in which the second portion extends is smaller than a dimension of the first portion (331) in a direction in which the first portion extends.

### Clause 10.

The semiconductor device (A10) according to clause 9, wherein a dimension in the first direction (z) of the second portion (332) gradually decreases with increasing distance from the first portion (331).

### Clause 11.

The semiconductor device (A10) according to any one of clauses 6 to 10, further comprising a sealing resin (50) covering the semiconductor element (10) and the first wire (30),
wherein the first terminal (21) is exposed from the sealing resin (50).

### Clause 12.

The semiconductor device (A20) according to clause 11, wherein the sealing resin (50) includes a third surface (51) facing the same side as the first surface (211A) in the first direction (z), and
a fourth distance (d4) between the third surface (51) and the first cross section (S1) in the first direction (z) is greater than a sum of the second distance (d2) and a dimension in the first direction (z) of the first cross section (S1).

### Clause 13.

The semiconductor device (A10) according to clause 11, wherein the first wire (30) contains aluminum.

### Clause 14.

The semiconductor device (A10) according to clause 11, wherein the first wire (30) contains copper.

### Clause 15.

The semiconductor device (A10) according to clause 11, further comprising a second terminal (22) electrically connected to the semiconductor element (10) and exposed from the sealing resin (50), wherein
the semiconductor element (10) includes a second electrode (12) located opposite to the first electrode (11) in the first direction (z), and
the second electrode (12) is conductively bonded to the second terminal (22).

### Clause 16.

The semiconductor device (A10) according to clause 15, wherein the second terminal (22) includes a reverse surface (223B) facing away from the second surface (11A) in the first direction (z), and
the reverse surface (223B) is exposed from the sealing resin (50).

### Clause 17.

The semiconductor device (A10) according to clause 16, further comprising a third terminal (23) electrically connected to the semiconductor element (10) and exposed from the sealing resin (50), wherein
the semiconductor element (10) includes a third electrode (13) located on the same side as the first electrode (11) in the first direction (z), and
the third terminal (23) is electrically connected to the third electrode (13).

### Clause 18.

The semiconductor device (A10) according to clause 17, further comprising a second wire (40) conductively bonded to the third electrode (13) and the third terminal (23),
wherein the second wire (40) is covered with the sealing resin (50).

### Clause 19.

The semiconductor device (A10) according to clause 18, wherein a diameter of the second wire (40) is smaller than a dimension in the first direction (z) of the first cross section (S1).

### Clause 20.

A method for manufacturing a semiconductor device (A10), the method comprising forming a first wire (30) conductively bonded to a semiconductor element (10) and a first terminal (21),
the semiconductor element (10) including a first electrode (11) located on one side in a first direction (z),
the first wire (30) including a main part (31), a first bond part (32) connected to one end of the main part (31) and conductively bonded to the first electrode (11), and a second bond part (33) connected to another end of the main part (31) and conductively bonded to the first terminal (21), wherein
in forming the first wire (30), the first bond part (32), the main part (31), and the second bond part (33) are formed in a mentioned order by working a metal material using a bonding tool (80), and
in forming the second bond part (33), the bonding tool (80) is turned around an axis (N) along the first direction (z), and then the second bond part (33) is cut away from the metal material.

### Clause 21.

The semiconductor device (A10) according to clause 3, wherein as viewed in the first direction (z), an angle (α2) formed between the main part (31) and the second bond part (33) is greater than an angle (α1) formed between the main part (31) and the first bond part (32).

### Clause 22.

The semiconductor device (A10) according to clause 7, wherein a sum of the second distance (d2) and a dimension in the first direction (z) of the first cross section (S1) is 70% or more of the third distance (d3).

### Clause 23.

The semiconductor device (A30) according to clause 9, wherein the first surface (211A) includes a first region (211B), and a second region (211C) extending from the first region (211B) to a side where the semiconductor element (10) is located as viewed in the first direction (z), and
as viewed in the first direction (z), the main part (31) overlaps with each of the first region (211B) and the second region (211C).

### Clause 24.

The semiconductor device (A10) according to clause 17, wherein the sealing resin (50) includes a first side surface (53) facing in a direction orthogonal to the first direction (z), and
a portion of each of the first terminal (21) and the third terminal (23) protrudes from the first side surface (53).

### Clause 25.

The semiconductor device (A10) according to clause 24, wherein a portion of the second terminal (22) protrudes from the first side surface (53).

### REFERENCE NUMERALS

A10, A11, A12, A13, A20, A30: Semiconductor device 10: Semiconductor element
11, 12, 13: First electrode, Second electrode, Third electrode 11A: Second surface
21: First terminal 211: First inner portion
211A: First surface 212: First outer portion
22: Second terminal 221: Second inner portion
222: Second outer portion 223: Pad portion
223A: Mount surface 223B: Reverse surface
23: Third terminal 231: Third inner portion
232: Third outer portion 29: Bonding layer
30: First wire 31: Main part
32, 33: First bond part, Second bond part
331, 332: First portion, Second portion 40: Second wire
50: Sealing resin 51, 52: Third surface, Fourth surface
53, 54: First side surface, Second side surface 80: Bond portion
81: Wedge portion 82: Guide portion
83: Cutting section 89: Metal material
S1, S2: First cross section, Second cross section d1 to d4: First distance to Fourth distance
z, x, y: First direction, Second direction, Third direction

1. A semiconductor device comprising:
a semiconductor element including a first electrode located on one side in a first direction;
a first terminal electrically connected to the first electrode; and
a first wire conductively bonded to the first electrode and the first terminal, wherein
the first wire includes a main part, a first bond part connected to one end of the main part, and a second bond part connected to another end of the main part,
the first bond part is conductively bonded to the first electrode,
the second bond part is conductively bonded to the first terminal, and
as viewed in the first direction, a direction in which the second bond part extends differs from a direction in which the main part extends.

2. The semiconductor device according to claim 1, wherein as viewed in the first direction, a direction in which the first bond part extends differs from the direction in which the main part extends.

3. The semiconductor device according to claim 2, wherein as viewed in the first direction, the direction in which the second bond part extends differs from the direction in which the first bond part extends.

4. The semiconductor device according to claim 2, wherein the first terminal includes a first surface which faces the one side in the first direction and to which the second bond part is conductively bonded,
the main part includes a first cross section and a second cross section that are sections perpendicular to the direction in which the main part extends,
the first cross section is located farthest from the first surface in the first direction,
the second cross section forms a boundary between the main part and the second bond part, and
a ratio of a second distance between the first surface and the first cross section in the first direction to a first distance between the first cross section and the second cross section as viewed in the first direction is 25% or more.

5. The semiconductor device according to claim 4, wherein a dimension in the first direction of the first cross section is greater than a dimension in the first direction of the semiconductor element.

6. The semiconductor device according to claim 4, wherein the first electrode includes a second surface which faces the same side as the first surface in the first direction and to which the first bond part is conductively bonded, and
the first surface is located between the second surface and the first cross section in the first direction.

7. The semiconductor device according to claim 6, wherein a sum of the second distance and a dimension in the first direction of the first cross section is smaller than a third distance between the first surface and the second surface in the first direction.

8. The semiconductor device according to claim 7, wherein the second bond part includes a first portion connected the main part and a second portion located opposite to the main part with respect to the first portion, and
a dimension in the first direction of the second portion is smaller than a dimension in the first direction of the second cross section.

9. The semiconductor device according to claim 8, wherein as viewed in the first direction, a dimension of the second portion in a direction in which the second portion extends is smaller than a dimension of the first portion in a direction in which the first portion extends.

10. The semiconductor device according to claim 9, wherein a dimension in the first direction of the second portion gradually decreases with increasing distance from the first portion.

11. The semiconductor device according to claim 6, further comprising a sealing resin covering the semiconductor element and the first wire,
wherein the first terminal is exposed from the sealing resin.

12. The semiconductor device according to claim 11, wherein the sealing resin includes a third surface facing the same side as the first surface in the first direction, and
a fourth distance between the third surface and the first cross section in the first direction is greater than a sum of the second distance and a dimension in the first direction of the first cross section.

13. The semiconductor device according to claim 11, wherein the first wire contains aluminum.

14. The semiconductor device according to claim 11, wherein the first wire contains copper.

15. The semiconductor device according to claim 11, further comprising a second terminal electrically connected to the semiconductor element and exposed from the sealing resin, wherein
the semiconductor element includes a second electrode located opposite to the first electrode in the first direction, and
the second electrode is conductively bonded to the second terminal.

16. The semiconductor device according to claim 15, wherein the second terminal includes a reverse surface facing away from the second surface in the first direction, and
the reverse surface is exposed from the sealing resin.

17. The semiconductor device according to claim 16, further comprising a third terminal electrically connected to the semiconductor element and exposed from the sealing resin, wherein
the semiconductor element includes a third electrode located on the same side as the first electrode in the first direction, and
the third terminal is electrically connected to the third electrode.

18. The semiconductor device according to claim 17, further comprising a second wire conductively bonded to the third electrode and the third terminal,
wherein the second wire is covered with the sealing resin.

19. The semiconductor device according to claim 18, wherein a diameter of the second wire is smaller than a dimension in the first direction of the first cross section.

20. A method for manufacturing a semiconductor device, the method comprising forming a first wire conductively bonded to a semiconductor element and a first terminal,
the semiconductor element including a first electrode located on one side in a first direction,
the first wire including a main part, a first bond part connected to one end of the main part and conductively bonded to the first electrode, and a second bond part connected to another end of the main part and conductively bonded to the first terminal, wherein
in forming the first wire, the first bond part, the main part, and the second bond part are formed in a mentioned order by working a metal material using a bonding tool,
in forming the second bond part, the bonding tool is turned around an axis along the first direction, and then the second bond part is cut away from the metal material.
